(19) United States
(12) Patent Application Publication
(10) Pub. No.: US 2025/0077724 A1
(43) Pub. Date: Mar. 6, 2025

(54) VIRTUAL AND MIXED SPACE-TIME SCALABLE AMALGAMATION SYSTEM

(71) Applicant: Worcester Polytechnic Institute, Worcester, MA (US)

(72) Inventors: Vladimir V. Vantsevich, Worcester, MA (US); Lee Moradi, Worcester, MA (US); Siyuan Zhang, Shrewsbury, MA (US); Masood Ghasemi, Shrewsbury, MA (US); Jesse R. Paldan, Novi, MI (US)

(21) Appl. No.: 18/821,632

(22) Filed: Aug. 30, 2024

Related U.S. Application Data
(60) Provisional application No. 63/536,059, filed on Aug. 31, 2023.

(51) Int. Cl. G06F 30/15

(52) U.S. Cl. CPC G06F 30/15

(57) ABSTRACT

A Metaverse Laboratory (ML) is a self-contained comprehensive research and development (R&D) laboratory facility for hybrid modeling and simulation, conceptual and engineering design, prototyping, and experimentation in an operational environment (real, virtual, or augmented) by analyzing consequences based on simulated or actual (live) inputs from either human actors and/or predetermined scenarios. A physical facility encloses a rendering area configured to receive projected images and physical devices or objects. User interaction may be accompanied by image rendering goggles in conjunction with physical interactions with vehicles, objects and/or other users disposed in the rendering area. Computing equipment for driving a rendered scenario directs the outputs including visual and tactile feedback according to the scenario, and input from sensors and users in the rendering area determines a computed response. The collective facility provides a generalized environment for programmed realities for modeling and simulation combined with tangible objects, devices and human actors.

### RELATED APPLICATIONS

This patent application claims the benefit under 35 U.S.C. § 119(e) of U.S. Provisional Patent App. No. 63/536,059, filed Aug. 31, 2024, entitled “VIRTUAL AND MIXED SPACE-TIME SCALABLE AMALGAMATION SYSTEM,” incorporated herein by reference in entirety.

### BACKGROUND

Virtual reality, once a technology pursued for computer gaming and entertainment, has evolved into a viable medium for full scale simulations and research of electronically modeled, real world entities. While virtual reality is often employed as somewhat of an umbrella term for multimedia, 3-dimensional rendering, modern computing hardware allows realistic and accurate simulations of concrete settings and actions for business, scientific, trending, and of course, entertainment and film. A somewhat hybrid version, augmented reality, incorporates generated media and images with reality in a technology that superimposes a computer-generated image on a user's view of the real world, thus providing a composite view.

### SUMMARY

A Metaverse Laboratory (ML) is a self-contained comprehensive research and development (R&D) laboratory facility for hybrid modeling and simulation, conceptual and engineering design, prototyping, and experimentation of a next generation system capable of predicting incoming dynamic changes in an operational environment (real, virtual, or augmented) by analyzing consequences based on simulated or actual (live) inputs from either human actors and/or predetermined scenarios. A physical facility encloses a rendering area configured to receive projected images and physical devices or objects. User interaction in the rendering area may be accompanied by image rendering (virtual reality or augmented reality) goggles in conjunction with physical interactions with vehicles, objects and/or other users disposed in the rendering area. Computing equipment for driving a rendered scenario directs the outputs including visual and tactile feedback according to the scenario, and input from sensors and users in the rendering area determines a computed response. The collective facility provides a generalized environment for programmed realities for modeling and simulation combined with tangible objects, devices and human actors.

Configurations herein are based, in part, on the observation that computer based simulations are often employed for predicting or estimating a result of a particular action or occurrence without requiring manifestation of the action or occurrence. Entertainment had been an early use of such simulations, as in a generated rendering, many aspects of the corresponding “reality” can be omitted and still achieve an entertainment value, such as in a video game. Simulation value as a reliable indicator of actual events becomes more tenuous as an omission or inaccuracy in the simulation could have substantial negative effects, such as in building construction, vehicle design, or monetary investments.

Unfortunately, conventional approaches to comprehensive computer simulation and modeling suffers from the shortcoming that accurate identification of relevant factors or inputs, coupled with the expense of computing and rendering hardware for ensuring a true simulation, is often inconsistent with a cost or budget of the project or matter simulated. Restating, the cost, burden or effort of generating a reliable and accurate simulation exceeds the benefit that could be provided by the conventional simulation. Accordingly, configurations herein substantially overcome the shortcomings of conventional modeling approaches by providing a self-contained, standalone facility adaptable to a variety of simulation and modeling tasks, coupled with computing facilities configured for supporting a robust modeling of predetermined and/or dynamic scenarios.

Configurations herein provide a baseline facility with computing and rendering hardware amenable to a variety of simulation and modeling tasks. The facility encompasses a combination of actual users and devices (“real” reality), augmented reality (AR) and virtual reality in a physical rendering environment equipped with projection and holographic capability for visual simulation, physical devices and vehicles navigable around the simulation environment, and VR goggles or headsets for physical user interaction in the rendering environment. A robust arrangement of rendering and simulation processors gathers input from the environment and drives the rendered simulation through visual projection, vehicle operation, user headset images and other parameters which can be computed and directed, rendered or displayed.

In further detail, in a computing environment for simulation and testing of a physical deployment of vehicles in a generated terrain environment, a system for evaluation of operational scenarios includes a deployment vehicle coupled to a physical system cluster, where the physical system cluster is configured for controlling vehicle movement and receiving sensor feedback from the deployment vehicle. A human experience cluster couples to one or more users, each wearable rendering device for generating user feedback, such that the human experience cluster is in communication with the physical system cluster for receiving signals based on the controlled vehicle movement and sensor feedback. A communication cluster in communication with the physical system cluster and the human experience cluster is configured for rendering a real reality (RR) environment, an augmented reality (AR) environment and a virtual reality (VR) environment, such that each of the RR, AR and VR environments is rendered in a time scale independent of a time scale of the others of the RR, AR and VR environments.

### BRIEF DESCRIPTION OF THE DRAWINGS

The foregoing and other objects, features and advantages of the invention will be apparent from the following description of particular embodiments of the invention, as illustrated in the accompanying drawings in which like reference characters refer to the same parts throughout the different views. The drawings are not necessarily to scale, emphasis instead being placed upon illustrating the principles of the invention.

FIG. 1 is a context diagram of a computing environment suitable for use with configurations herein;

FIG. 2 is a schematic view of the system supporting simulations and modeling in the environment of FIG. 1;

FIG. 3 is a diagram of augmented reality (AR) and virtual reality (VR) rendered to a user in the configuration of FIG. 2;

FIG. 4 is an example of simulation using electromagnetic interference experienced by a vehicle sensor in the environment of FIGS. 1 and 2;

FIG. 5 shows a schematic drawing of a TEM cell configured for RF interference testing in the environment of FIGS. 1 and 2;

FIG. 6 shows a rotational speed sensor in the vehicle of FIG. 4;

FIG. 7 shows a timeline depicting varied time-space scales, or frames of reference, in the environment of FIGS. 1 and 2; and

FIG. 8 is a block diagram of the time-space scales of FIG. 7.

### DETAILED DESCRIPTION

The description below describes the disclosed system implemented in a test facility for providing the physical and “real world” aspects for live user interaction. Complementary and simultaneous rendering of Augmented Reality (AR) and Virtual Reality (VR) are implemented by the computing equipment and instructions encoded thereon for providing a full RR (Real Reality), AR and VR simulation. Users may experience, observe and optionally participate in the simulation through residence in the facility, either at an interactive station with a keyboard and screen interface, or as a live presence in the rendering area of the facility using VR/AR goggles and optionally, manipulating a device or object, such as a vehicle, coupled to the system with appropriate sensors.

As digital technologies are rapidly accelerating and autonomous systems (ASs) are becoming an integral part of human life in numerous activities in, there is a need to consider and evaluate fundamentally new scientific principles, methodologies and corresponding laboratory facilities that can meet the meaningful directions and trends in the digital world. The Metaverse Laboratory (ML) is a self-contained, and self-sustained research and development (R&D) laboratory facility to support hybrid modeling and simulation, conceptual and engineering design, prototyping, and experimentation of next generation of autonomous systems capable to:
1. Predict changes in an operational environment (real, virtual, or augmented) by analyzing consequences of the future environmental actions or changes for the autonomous systems to investigate the changes in detail by scaling the space and time, and based on that analysis:
2. Make decisions for real-time actions faster-than-real-time or within time margins acceptable for agile (extremely fast, precise, and preemptive/proactive) dynamics of the autonomous systems.

The beneficial innovation of the Metaverse Laboratory, which aims to reshape the future of autonomous system R&D facilities, is based on the recently developed approach to fundamentals of a Metaverse that is defined here succinctly as a set of the real realities (RRs), virtual realities (VRs), and augmented realities (ARs), which may have different spacetime configurations and/or scale with optional human activity. The term “metaverse” has been used rather loosely in technical and gaming circles, and possibly overused in marketing circles to connote broad reaching and advanced technology.

The “Metaverse” is meant to define a virtual-reality space in which users can interact with a computer-generated environment and other users, entities, and objects. A metaverse defines a virtual context (world/universe) with actors defined by an avatar, a virtual entity interacting in the context which may or may not correspond to a human actor. Such a virtual reality space is therefore capable of representing not only Earth, but rather may reach, for example, satellite and celestial bodies since it is a virtual representation. However, as a practical matter, rendering and simulation is equally as effective when undertaken in an earth domain, such as vehicular terrain navigation and EMF (Electromagnetic Frequency) interference with electronic systems on the vehicles in the simulation.

In general, an Autonomous System (AS) is meant to designate a computing entity, facility or cluster having a designated policy set by a particular entity, such as a corporation or enterprise. Often this translates to a set of Internet routable IP prefixes belonging to a network or a collection of networks that are all managed, controlled and supervised by a single entity or organization.

Unlike existing and currently emerging approaches, the technical benefit and intellectual merit of the proposed approach is that the Metaverse is formulated and developed as cyber-physical convergent and/or divergent, spacetime amalgamations of the real realities with virtual realities and augmented realities. Based on such formulation, computational methods and logic are implemented in the hardware/software/human environment of the Metaverse with the human-autonomy and autonomy-autonomy teaming to manage times running differently in multiple RRs, VRs and ARs, which are also characterized by the space scalability property, i.e., additionally to differently running times, some areas of RRs, VRs and ARs may have different space scale compared to the other areas of the same VRs and ARs. Amalgamation is particularly beneficial when at least the AR and VR environments operate at a time scale faster than a time scale of the RR environment.

The Metaverse Laboratory serves as a self-contained facility to enable research in modeling and simulations, design, prototype, and test of autonomous systems, and then successfully transition conceptually new R&D studies in novel technologies from a proof-of-concept stage forward. A modular-based approach allows for reconfiguring the ML and studying autonomous systems for various applications. Thus, the general vision is that the ML will respond to the technology and innovation needs of different sectors including automotive, transportation, healthcare, robotics and automation, manufacturing, and education. The ML will support and provide services for these sectors in modeling, simulation, design and prototyping, teaching, training, monitoring, analysis, diagnosis, prediction, control, and automation. Through such services, the risk associated with the production costs, staff shortages, bodily injuries/threats, system failures and dangers will be reduced, systems efficiency, precision, and reliability will be promoted, and productions time and service durations will be reduced.

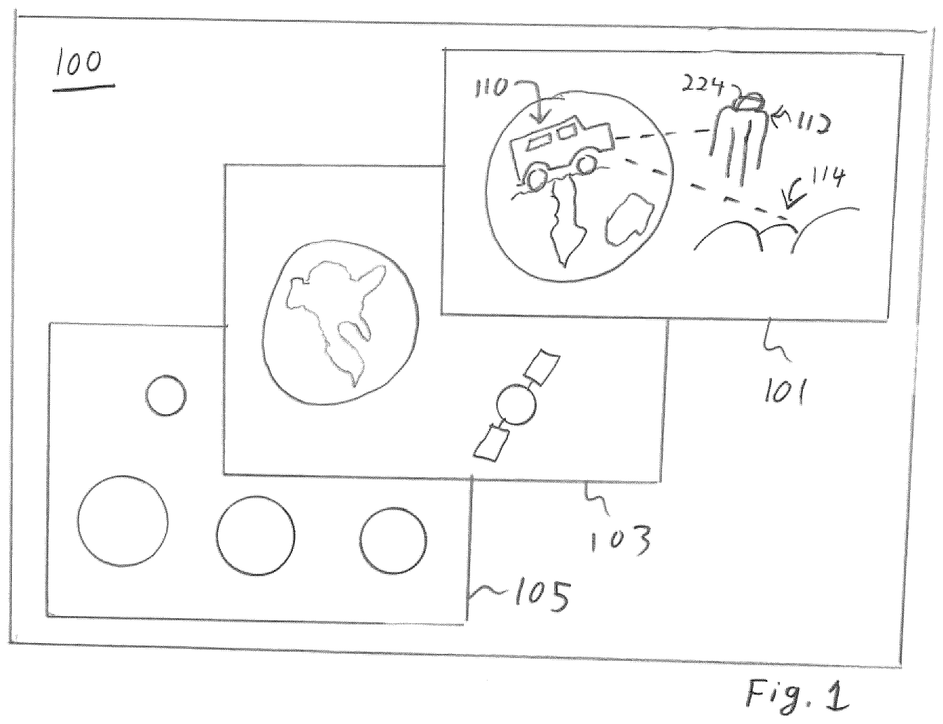

FIG. 1 is a context diagram of a computing environment suitable for use with configurations herein. Referring to FIG. 1, the ML facility 100 expects the amalgamation of RRs, VRs, and ARs at three levels, including the Earth Worldline 101, Earth—Satellite Worldline 103, and Celestial Worldline 105. As demonstrated herein, a simulation in Level-1 Metaverse of the Earth Worldline provides substantial simulation and modeling capability, however may be extended to the Earth—Satellite Worldline 103 and Celestial Worldlines 105. Within each worldline 101, 103 and 105, real (unsimulated or human tangible) reality 110, augmented reality 112 and virtual reality 114 may be demonstrated. Aptly named “real” reality refers to physical objects, things and spaces which may experienced and touched, such as a physical vehicle or a landscape. User wearable rendering device includes visual goggles 224 for perceiving and rendering the AR environment. Augmented reality 112 may include elements of real reality, but with electronically driven enhancements or additions, such as AR goggles that permit sight of physical (real reality) elements but superimpose or overlay virtual elements through the goggles. Virtual reality 114 may include a completely electronic landscape or object—in other words, entirely electronically represented.

Conceptually, the ML encompasses an R&D facility, in which the amalgamation of RRs, VRs, and ARs is set up at the three levels shown in FIG. 1 that may require the same or different worldlines depending on a technical problem's complexity and autonomous system's application. A worldline in general is defined as the aggregate of kinematic and dynamic parameters of an autonomous system in a spacetime configuration. The three levels of amalgamation include:
101: Earth Worldline (EW)
103: Earth—Satellite Worldlines (ESWs)
105: Celestial Worldlines (CWs).

For the first level of Earth Worldline (Level-1 Metaverse), an ML user or multiple users on Earth (humans or AI-based autonomous systems in future projects) operate(s) and function(s) in the same worldline of Earth while they can virtualize, augment, and amalgamate the realities in different spacetime controllable configurations to predict future movements of autonomous systems and their interactions with each other and environments in real-time or close to real-time. Modeling helps demonstrate how a spacetime interval between any two events is independent of the inertial frame of reference in which they are recorded.

In Earth-Satellite Worldlines (the second level of amalgamation of RRs, VRs, and ARs, i.e., Level-2 Metaverse), the rendered environments include kinematic parameters depicting earth and satellite bodies of the earth, and define an amalgamation of the earth and at least one satellite. Thus, an ML user or multiple users on Earth and Earth's satellites operate and function in different worldlines of Earth and the satellites while the users can virtualize, augment, and amalgamate the realities in different spacetime controllable configurations to predict future movements of autonomous systems and their interactions with each other and environments in real-time or close to real-time on Earth.

In Celestial Worldlines (i.e., at the third level of amalgamation of RRs, VRs, and ARs that is Level-3 Metaverse), the rendered environments include kinematic parameters depicting the earth and celestial bodies. Therefore, an ML user or multiple users on Earth, Earth's satellites, and on other celestial bodies of the Universe operate and function in different worldlines while the users can virtualize, augment, and amalgamate the realities in different spacetime controllable configurations to predict future movements of autonomous systems and their interactions with each other and environments in Earth's real-time or close to real-time on Earth, and faster/slower than Earth's real-time.

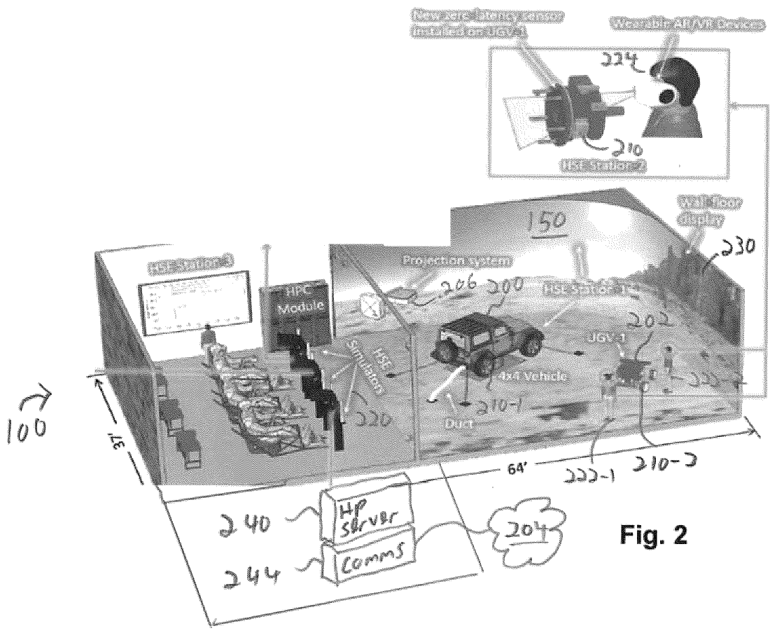

From this conceptual context, FIG. 2 is a schematic view of the physical facility and computing devices supporting simulations and modeling in the environment of FIG. 1. Referring to FIGS. 1 and 2, FIG. 2 illustrates interfaces with Level-1, -2, and -3 of FIG. 1. It can be observed that level 1 includes a communications network 204 for remote, Internet based computing or information. Supporting the facility are three computational banks or clusters of processor based computing equipment (processors and memory). At a minimum, the ML facility 100 houses deployment vehicle 200, and a media projection system 206 configured for rendering visual images depicting the AR and VR environments. A wall-floor display 230 is responsive to the media projection system 206 for visual renderings to users within the test facility.

A Cyber-Physical System Cluster (CPS) includes autonomous/unmanned and manned physical systems residing in a rendering area 150, which integrate exteroceptive and proprioceptive sensing, actuation, AI-decision making, and intelligent controls. This may include a deployment vehicle coupled to a physical system cluster, the physical system cluster configured for controlling vehicle movement and receiving sensor feedback from the deployment vehicle. In FIG. 2, the CPS is represented by a physical all-terrain vehicle 200 that is lifted with a jacking system and strapped to the reinforced floor with an exhaust pipe connected to the outside via a flexible duct. This vehicle can operate in both manned and unmanned modes.

The CPS also includes one or more unmanned ground vehicles (UGVs) 202. Each UGV 202 may be steered by turning/pivoting the front wheels or a skid-turning system, in which each wheel's torque and rotational speed are individually and autonomously controlled by simulation logic. The vehicles 200, 202 each also include a zero-latency sensor 210-1 . . . 210-2 (210 generally) of the UGV wheel rotational speed that is modelled and simulated. Each of the vehicles may also employ control units and advanced proprioceptive and exteroceptive sensor systems, including GPS/IMU, (Global Positioning System/Inertial Measurement Unit) LiDAR (Light Detection and Ranging), stereo-camera, and others as called for by a particular scenario.

A Human-System-Environment Cluster (HSE) 220 interfaces with ML local users 222-1 . . . 222-2 (222 generally) and RRs, VRs, and ARs. This provides a cluster for the human experience coupled to a user wearable rendering device, such as goggles 224, for generating user feedback, such that the human experience cluster is in communication with the physical system cluster for receiving signals based on the controlled vehicle movement and sensor feedback. Specifically, the example configuration includes five workstations or processors interface with the modeling and simulation, design and analysis, and experimentation processes.
1. Station-1 is to virtualize and visualize interactions of manned and autonomous systems with environments
2. Station-2 is to augment the reality and visualize its impact on autonomous system behavior/dynamics
3. Station-3 is to analyze results of augmentation
4. Station-4 is to design an autonomous system using a virtual reality
5. Station-5 is to conduct experimentation of the autonomous system with augmented characteristics.

In principle, with such station configurations, the HSE can be applicable to a variety of autonomous systems. In this project, the HSE will be used to design the new RPM-zero-latency sensor. At Station-1, which includes the Wall-Floor Display System 230, virtualizes and visualizes the simulation of different environments for a driver operating the all-terrain vehicle 202 through a given terrain. At Station-2, two users equipped with AR/VR wearable devices simulate and virtualize the impact of an adversary electromagnetic field on the RPM-zero-latency sensor signal and its impact on the movement of the UGV 202 that assists to the all-terrain vehicle 202 with its mission fulfilment. A user in the far-left corner of the ML Modeling and Simulation Unit, which is Station-3, analyzes the electromagnetic field's impact on characteristics of the sensor in the form of interactive graphs. Station-4 supports virtually design of the RPM-zero-latency sensor by utilizing the holographic system, and Station-5 may be employed, for example, for testing vehicles 200 equipped with the zero latency sensor 210. Additional HSE simulators may also be employed adjacent to the rendering area 150.

A High Computational and Communication Cluster (HC3) 240 includes 3 modules: a High-Performance Computing (HPC) Module, High-Performance Server (HPS) Module, and Network Module. The HPC and HPS modules will process all computational real-time and faster-than-real-time processes in Level-1 Metaverse's Real Realities, Virtual Realities, and Augmented Realities. The Network Module will supports interconnection of Metaverse elements via 5G+ or available network infrastructure, and provide connectivity and data interexchange among the Cyber-Physical System Cluster and the Human-System-Environment Cluster, and thus, provide communicational interactions between human users and all realities of the ML facility 100. The net result is a cluster in communication with the physical system cluster and the human experience cluster for rendering a real reality (RR) environment, an augmented reality (AR) environment and a virtual reality (VR) environment, each of the RR, AR and VR environments rendered in a time scale independent of a time scale of the others of the RR, AR and VR environments.

An example configuration of the disclosed rendering area 150 depicts vehicles 200, 202 and utilizes the zero latency sensor 210 for sensing rotational speed. Conventional rotational speed sensors employed in traction control systems of automobiles are characterized by 200 to 250 ms latency in producing the signal, which diminishes the efficiency of the systems, and thus, reduces vehicle performance characteristics. The zero-latency rotational speed sensor couples to the deployment vehicles 200, 202 for generating a position and a speed of the deployment vehicle. The disclosed zero latency sensor is based on agile tire slippage dynamics that is studied as an extremely fast and exact response of the tire-soil couple to (i) the tire dynamic loading, (ii) transient changes of gripping and rolling resistance conditions on uniform stochastic terrains and (iii) rapid transient changes from one uniform terrain to a different uniform terrain. The zero latency sensor 210 is employed as an example sensor in the ML facility 100, other sensors may be employed for various physical parameters. As invoked in the example ML facility 100, the sensor is employed in control systems of the vehicles 200, 202 related to predicting future optimal maneuvers in changing and/or adversarial environments.

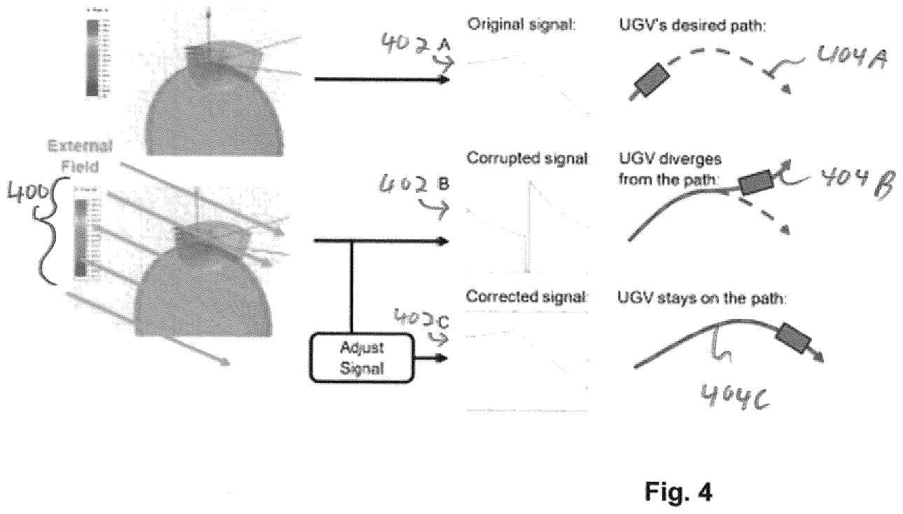

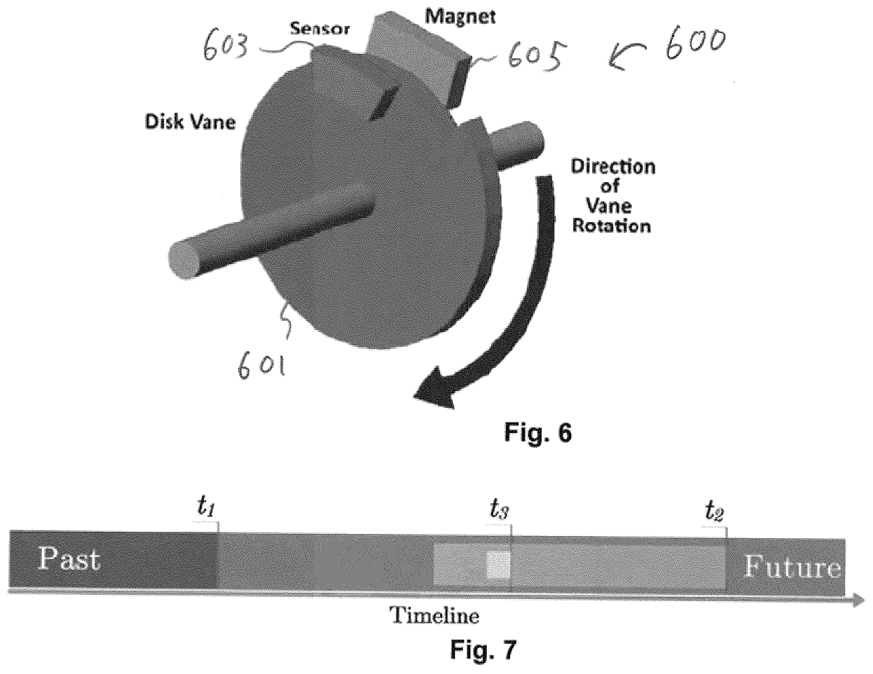

Configurations employ the zero latency sensor 210 as an example of a sensor in the rendering area 150. Any number of suitable sensors may also be included and/or modeled, depending on the needs of a particular simulation configuration. FIG. 6 shows a rotational speed sensor assembly 600 in the vehicle of FIG. 4. With specific regard to the zero latency sensor 210, the proposed sensor uses a disk-vane type configuration with a vane shape as depicted in FIG. 6 and a magnetic field sensor 603 opposed from a bias magnetic field provided by a permanent magnet 605. Instead of a tooth-type vane, a disk 601 with a spiral shape vane is used in the proposed sensor as shown in FIG. 6. Unlike common Hall effect sensors, the sensor 600 is based on creating a continuous signal that does not require to be digitized.

With an always-changing value of the spiral's radius at points along the edge of the vane, the area of the sensor blocked by the vane is also always changing as the vane rotates. Thus, magnetic flux density will decrease proportional to the area of the sensor which is not covered by the vane and Hall voltage VH can be expressed as follows:

$${V}_{H} = {r}_{H} \frac{I}{{s}_{t}} {B}_{max} ( 1 - \frac{{A}_{vane}}{{A}_{sen}} ) + {V}_{q}$$

where r_{H} is a constant, I is the current, sₜ is the sensor thickness, Bₘₐₓ is the max flux density, Aₛₑₙ is the sensor area, Aᵥₐₙₑ is the vane's area overlapping the sensor, and V_{q} is the voltage at no magnetic field.

In an example configuration, a manned or unmanned exploratory navigation of uncharted terrain using the vehicles 200, 202 is demonstrated. Such a traversal may occur in remote or hostile tactical regions, or exploration of celestial bodies. Such a scenario may be simulated in the ML facility 100 as a reconnaissance task to assist the all-terrain vehicle 200 with a driver to move through severe unprepared terrain, using stations 1 and 2 as described above. The real UGV 202, augmented with the RPM-zero-latency sensor 210, may be simulated in Station-2 and analyzed in Station-3 using the sensor parameters and characteristics obtained through the virtual/holographic design process in Station-4.

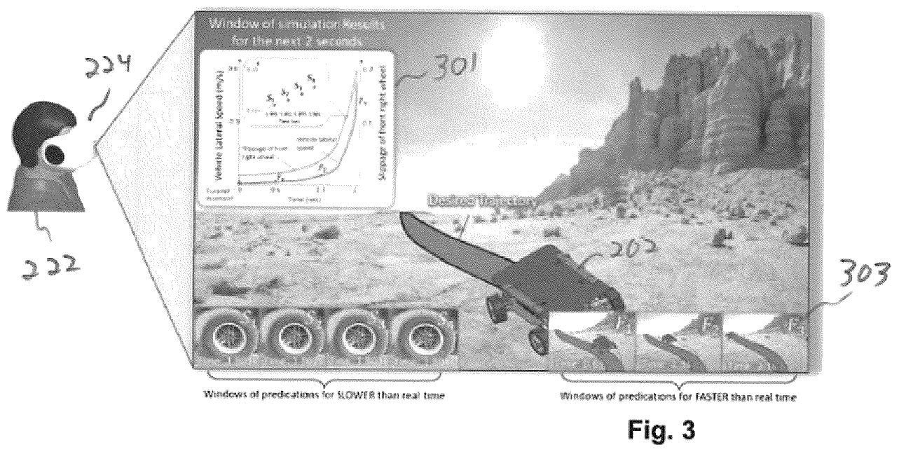

The ML facility 100 is configured to deploy an EMF source for delivering an electromagnetic interference input. During the mission fulfilment, the UGV 202 computational model, “equipped” with the RPM-zero-latency sensor model, will be subjected to an adversary attack in the form of external electromagnetic fields that negatively impact the sensor signal. The distorted sensor signal may impact UGV 202 movement and change the trajectory path of this vehicle. The main engineering outcome of this simulation will be the degree of distortion at which the sensor 220 can provide a robust signal that can be utilized in the control system. While subjected to the electromagnetic field, UGV 202 analyzes its future paths faster-than-real-time and communicates to the driver of the vehicle 200 about the best future path that UGV 202 will pursue in consideration of the corrupted signal, discussed further below with respect to FIGS. 3 and 4.

One aspect of the disclosed system is to predict or estimate changes in an operational environment, make decision on future optimal/reasonable action faster-than-real-time, and, when the future becomes a reality, to ensure that the real-time actuation is fulfilled according with the decision made. Thus, the present and the future should be amalgamated in such autonomous systems to provide for their operation. Consequently, a significant feature of the ML facility 100 is to amalgamate representations of the present and the future through spacetime amalgamation of different realities.

Conceptually, this is achieved by cyber-physical spacetime amalgamation of interconnected and interactive RR, VR, and AR. This technical approach to set up RR, VR, and AR in the metaverse lab is based on spacetime configurations which are observed in the Universe, and which differ depending on the gravitational potential and speed. For example, Minkowski spacetime for low gravitational potential is considered as a combination of 3-dimensional Euclidean space and time into a 4-dimensional manifold where the spacetime interval between any two events is independent of the inertial frame of reference in which they are recorded. The Minkowski distance or Minkowski metric is a metric in a normed vector space which can be considered as a generalization of both the Euclidean distance and the Manhattan distance. It is named after the Polish mathematician Hermann Minkowski.

The facility 100 has the property to scale differently in its different regions, i.e., different space regions, including objects and objects' parts/layers, may be (i) Large scaled to Micro- and Nano-worlds and/or (ii) Small scaled to Macro-worlds. Scalable Space applications will cardinally improve autonomous system visualization for the purposes of modeling and simulation and engineering design. Time in Metaverse will have the property to flow differently in different regions of physical and cyber space, i.e., time processes in different space regions may run (i) Faster than real time and (ii) slower than real time.

Different time flows/measurements in different regions provide a set of the spacetime configurations. The ML facility 100 is a human-centered system, in which humans may be an actor and a perceived human situation awareness is the outcome for the human operation in the different realities.

Thus, the Metaverse can be further detailed as a set of spacetime manifolds, in each of which the space is scalable and combined with a different time flow. It is important to emphasize that AR in the Metaverse does not necessarily augment RR. AR may augment a VR spacetime by introducing a new spacetime in that particular VR.

The question is on how the above-introduced definition of the Metaverse can be implemented in the Metaverse Laboratory. The technical approach to the Metaverse implementation is considered next for the three levels of the metaverse worldlines 101, 103 and 105.

FIG. 3 is a diagram of augmented reality (AR) and virtual reality (VR) rendered to a user in the configuration of FIG. 2. One of the advantages of AR and VR amalgamation is to define different timing references in each simulated scenario or reality. For example, the Level-1 metaverse 101 operates in the worldline of Earth, and time runs with the same pace for all users. Therefore, predicting the future of an autonomous system is possible by simulating future potential scenarios much faster than real-time. As an example, in FIG. 3, the autonomous vehicle 202 is simulated in a real-time VR1. The vehicle is moving on a desired trajectory path and predicting its future that is 2 seconds away from the current moment of time. This means that yet another simulation of the UGV 202 is running or executing much faster than real-time as an augmented reality of VR1, notated as AR1. Such a faster-than-real-time simulation in AR1 becomes possible by reducing the vehicle model fidelity and, thus, sacrificing to a reasonable degree accuracy of simulation results. In the lower right corner inset 303 of FIG. 3, three future time moments F₁, F₂, and F₃ of AR1 are illustrated to predict that the UGV 202 will become unstable and deviate from the desired path. This is due to a drastic increase of the vehicle lateral speed as the AR1 graph 301 shows in the upper left corner of FIG. 3. Another reason of the unstable motion is the increase of the front-right wheel slippage, which is also shown in that graph 301 inset. To learn more about the wheel slippage, the simulation is slowing down in AR2 (which is an augmented reality of AR1) shown for the time moments of S₁, S₂, S₃, and S₄. It should be emphasized that the slowed down time in AR2 is still running faster-than-real-time, therefore all the events in AR1 and AR2 are not interfering with the real time that is also running, and the vehicle model is moving forward along its path. A human operator may be the driver of the all-terrain vehicle 200 shown in FIG. 2 who is observing the above-described events either in real-time or off-line (i.e., after simulation completion) to analyze the operation performance of AI-control algorithms of UGV 202 and communication channels between the vehicles.

FIG. 4 is an example of simulation using electromagnetic interference experienced by a vehicle sensor in the environment of FIG. 3. Referring to FIGS. 1-4, the deployment 150 further includes an EMF source 400. The EMF source is directed towards the vehicle 202. In an example configuration, EMF source further comprises a Transverse Electro-Magnetic (TEM) cell, which is a compact alternative to an RF shielded enclosure room for EMF testing. In the test scenario, the deployed vehicle 202 further includes the zero-latency rotational speed sensor 210, such that the EMF source 400 induces an interference signal in the determined speed of the deployment vehicle 202.

While continuing its motion, an output signal 402A from the sensor 210 corresponds to the desired path 404A. UGV 202 is attacked with an external electromagnetic field source 400, and the RPM-zero-latency sensor output signal 402B is corrupted, causing the vehicle 202 to pursue a divergent path 404B. Therefore, incorrect sensor information goes to the controller and the UGV's mobility and maneuverability capabilities may become compromised. The sensor 210 employs an active protection from external electromagnetic fields to inform the operator of the all terrain vehicle 200 about the attack, autonomously adjust the signal to its non-corrupted value if possible, and provide the adjusted signal to the UGV 202 control system; the UGV is then able to continue its motion on the correct path 404C, resulting from the corrected signal 402C.

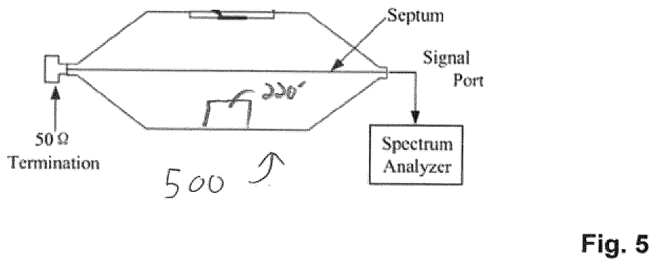

FIG. 5 shows a schematic drawing of a TEM cell 500 configured for RF interference testing in the environment of FIGS. 3 and 4. The TEM cell 500 is an enclosure acting as an electromagnetic transducer that is shielded to provide isolation from external electromagnetic fields. Within the enclosure lies conductive material, forming a section of transmission stripline that can be connected to standard coaxial cables. The interior of the cell acts as a waveguide and converts electric signals into homogeneous electromagnetic fields with approximately transverse mode distribution, similar to free space. The electric and magnetic field inside the cell can be accurately predicted using numerical methods.

Conventional testing for electromagnetic interference is typically done in a large, shielded chamber with multiple antennas with high space and cost requirements. The TEM cell 500 is an alternative for testing products but is confined to a smaller enclosed space 502, suitable for encapsulating the sensor under test 210′. The design of a digital twin of the sensor, tested on a simulated UGV 202, will enable testing the sensor's response to external electromagnetic fields early in development. This allows testing and research using UGV 202 and AR of the sensor 210 amalgamated with RR of the actual vehicle. Such amalgamation of RR augmented with AR or VR can be augmented with AR and simulated faster-than real-time to learn the future consequences of the electromagnetic attack.

In an example configuration, the rendering area 150 is particularly well suited to space-time amalgamations and simulations of vehicular mobility on a harsh or unknown landscape, as might be encountered in a remote area or exploitation of an unknown planet. To demonstrate agile (extremely fast, preemptive, and precise) mobility, the UGV 202 should be capable of predicting incoming future operational changes and making faster-than-real-time decisions to stay safe in severe and adversarial environments where conventional/manned vehicles cannot or should not operate. The approaches to autonomous foresight are referred to as optimal control, model predictive control, and model-agnostic and AI-based exploration to allow predicting several next seconds after building a predictive model of the environment. One particular limitation is that the applicability of a modeling and simulation for future dynamic prediction depends on its math computation complexity and hardware computational power. FIG. 7 shows a timeline depicting varied time-space scales, or frames of reference, in the environment of FIGS. 1 and 2. Referring to FIGS. 1-7, in the facility 100, multiple amalgamated virtual realities may be designed and developed to produce, as shown in FIG. 7, three configurations of t₁ (real-time), t₂ and t₃ (faster-than-real-time) with t₂ being faster than t₃. For scenarios in the rendering area 150, configurations of time may be defined by introducing different time lags associated with each of the timeframe references t₁, t₂ and t₃.

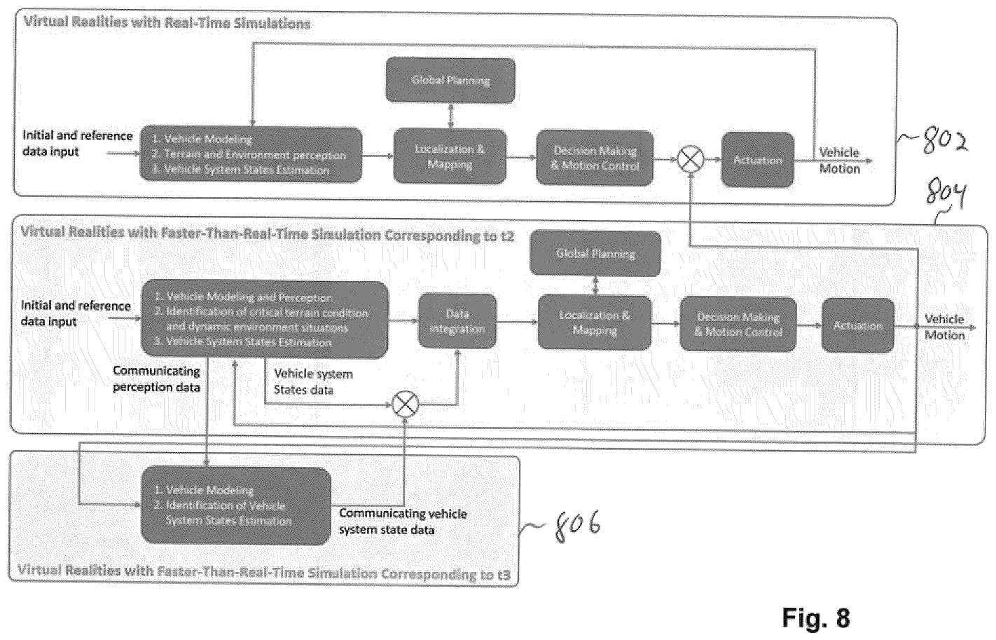

FIG. 8 is a block diagram of the time-space scales of FIG. 7. The three virtual reality contexts (VRs) 802, 804 and 805 shown in FIG. 8 run simultaneously in three different spacetime configurations. They are amalgamated through scaled times and active information exchange, which is utilized for decision-making and control implementation. These virtual co-simulated realities each have the capabilities to model and simulate all aspects relevant to the framework. Each VR corresponds to a respective time scale t₁, t₂ or t₃, and depicts parameters such as physical and cyber-physical vehicle systems, including powertrain (both internal combustion engine-based and fully electric) driveline, wheel and tire locomotion, suspension, and vehicle exteroceptive sensors (including LiDAR and camera) and proprioceptive sensor of the wheel rotational velocity. The rendering area 150 may depict/render/simulate challenging, unstructured terrain and environments. This includes deformable terrain (including topography and mechanical properties), static and dynamic obstacles, and objects (e.g., trees, buildings, agents, positive/negative obstacles). Terramechanics-based dynamic interactions between tires and deformable terrain, particularly in conjunction with the sensor 600, may be implemented. Other parameters include environmental perception: based on the exteroceptive sensor model data, the vehicle shall be able to perceive its surrounding objects and environment, and vehicle operational properties, including maneuver, mobility, and energy efficiency in various operational conditions, which are crucial for vehicle motion.

The rendering area 150 may therefore depict both Real-Time Simulation (RTS) and 2) Faster-Than-Real-Time Simulation (FTRTS). For RTS, the simulation time is synchronized with the real-world wall clock. For FTRTS, the simulation time is faster than the real-world wall clock. Models used for RTS and FTRTS must maintain sufficient accuracy, allowing for a defined margin of error that does not compromise the overall simulation objectives. This accuracy requirement is directly linked to the setting of the simulation step time. The acceptable error margin must be carefully calibrated to ensure that it does not significantly impact the reliability of simulation results while still enabling FTRTS performance.

The rendering area 150 therefore provides a co-simulated environment capable of graphically animating the UGVs moving in a challenging, unstructured environment based on the simulations including both online animation and offline animation.

For the online mode, the animation is generated at the same time as the computer simulation is processing, which allows the users to visualize the system behaviors at the current moment in real-time and at the moments of future events. It shall support real-time animation (RTA) and faster-than-real-time animation (FTRTA).

For the offline mode, the animation is generated after the entire computer simulation is completed. It is used to conduct further offline investigations of the vehicle behavior at any moment during the entire simulation. It shall support RTA, FTRTA, and slower-than-real-time animation (STRTA). For RTA, the animation is played synchronized with the real-world clock. For FTRTA, the animation is played faster than the real-world clock. For STRTA, the animation is played slower than the real-world clock.

It is noted that “real-time,” “faster-than-real-time,” and “slower-than-real-time” only indicate the animation play speed. In other words, any simulation (RTS, FTRTS, or STRTS) can be animated running in real-time, faster than real-time, or slower than real-time.

The all terrain vehicle 200 is user operable and defines a driving simulator of a conventional vehicle (i.e., operated by a human driver). The driving simulator with a driver may be part of the virtual reality simulations. The driving simulator included a steering wheel, throttle and brake pedals, a seat belt, and a transmission gearshift, and is capable of reflecting 3DOF movements at the driver's seat in real-time.

Those skilled in the art should readily appreciate that the programs and methods defined herein are deliverable to a user processing and rendering device in many forms, including but not limited to a) information permanently stored on non-writeable storage media such as ROM devices, b) information alterably stored on writeable non-transitory storage media such as solid state drives (SSDs) and media, flash drives, floppy disks, magnetic tapes, CDs, RAM devices, and other magnetic and optical media, or c) information conveyed to a computer through communication media, as in an electronic network such as the Internet or telephone modem lines. The operations and methods may be implemented in a software executable object or as a set of encoded instructions for execution by a processor responsive to the instructions, including virtual machines and hypervisor controlled execution environments. Alternatively, the operations and methods disclosed herein may be embodied in whole or in part using hardware components, such as Application Specific Integrated Circuits (ASICs), Field Programmable Gate Arrays (FPGAs), state machines, controllers or other hardware components or devices, or a combination of hardware, software, and firmware components.

While the system and methods defined herein have been particularly shown and described with references to embodiments thereof, it will be understood by those skilled in the art that various changes in form and details may be made therein without departing from the scope of the invention encompassed by the appended claims.

What is claimed is:

1. In a computing environment for simulation and testing of an unmanned physical deployment of vehicles in a generated terrain environment, a system for evaluation of operational scenarios, comprising:
a deployment vehicle coupled to a physical system cluster, the physical system cluster configured for controlling vehicle movement and receiving sensor feedback from the deployment vehicle;
a human experience cluster coupled to a user wearable rendering device for generating user feedback, the human experience cluster in communication with the physical system cluster for receiving signals based on the controlled vehicle movement and sensor feedback; and
a communication cluster in communication with the physical system cluster and the human experience cluster for rendering a real reality (RR) environment, an augmented reality (AR) environment and a virtual reality (VR) environment, each of the RR, AR and VR environments rendered in a time scale independent of a time scale of the others of the RR, AR and VR environments.

2. The system of claim 1 wherein at least the AR and VR environments operate at a time scale faster than a time scale of the RR environment.

3. The system of claim 1 further comprising a zero-latency rotational speed sensor, the zero-latency rotational speed sensor coupled to the deployment vehicle for generating a position and a speed of the deployment vehicle.

4. The system of claim 1 wherein the user wearable rendering device includes visual goggles for perceiving and rendering the AR environment.

5. The system of claim 1 wherein the rendered environments include kinematic parameters depicting earth and satellite bodies of the earth.

6. The system of claim 1 wherein the rendered environments include kinematic parameters depicting the earth and celestial bodies.

7. The system of claim 1 wherein the rendered RR, AR and VR environments define an amalgamation of the earth and at least one satellite.

8. The system of claim 1 further comprising an EMF source for delivering an electromagnetic interference input.

9. The system of claim 1 further comprising:
a test facility, the test facility housing the deployment vehicle;
a media projection system, the media projection system configured for rendering visual images depicting the AR and VR environments; and
a wall-floor display, the wall-floor display responsive to the media projection system for visual renderings to users within the test facility.

10. The system of claim 9 further comprising an EMF source, the EMF source directed towards the deployment vehicle, wherein EMF source further comprises a Transverse Electro-Magnetic (TEM) cell.

11. The system of claim 10 wherein the deployment vehicle further comprises:
a zero-latency rotational speed sensor for determining a speed of the deployment vehicle; and
an EMF source for inducing an interference signal in the determined speed.

12. The system of claim 3, wherein the zero-latency rotational speed sensor further comprises a continuous analog signal based on a magnetic flux responsive to a rotating wheel.

13. The system of claim 12, wherein the rotating wheel has a spiral shape and the analog signal is based on magnetic flux passing through the rotating wheel from a permanent magnet to a magnetic sensor.
